(19) United States
(12) Patent Application Publication
(10) Pub. No.: US 2025/0133876 A1
(43) Pub. Date: Apr. 24, 2025

(54) LIGHT-EMITTING DIODE CHIPS WITH LIGHT EXTRACTION FILMS AND RELATED METHODS

(71) Applicant: CreeLED, Inc., Durham, NC (US)

(72) Inventors: David Suich, Durham, NC (US); Michael Check, Holly Springs, NC (US); Colin Blakely, Raleigh, NC (US); Robert Wilcox, Rolesville, NC (US); Joseph G. Sokol, Durham, NC (US); Andre Pertuit, Raleigh, NC (US); Natalia da Silva Moura, Durham, NC (US)

(21) Appl. No.: 18/490,105

(22) Filed: Oct. 19, 2023

(51) Int. Cl. H01L 33/44; H01L 33/30; H01L 33/38

(52) U.S. Cl. CPC H10H 20/84; H10H 20/824; H10H 20/8312; H10H 20/034

(57) ABSTRACT

Light-emitting diode (LED) chips and, more particularly, LED chips with light extraction films and related methods are disclosed. Light extraction films include antireflective structures that are integrated within LED chip structures. Antireflective structures include one or more antireflective layers positioned to reduce internal reflections at various internal interfaces of LED chips. Certain LED chip structures include antireflective structures positioned between epitaxially grown active LED structures and carrier substrates on which the active LED structures are supported. Wafer level bonding sequences with one or more bonding layers are disclosed that facilitate integration of antireflective structures within LED chip structures.

### FIELD OF THE DISCLOSURE

The present disclosure relates to light-emitting diode (LED) chips and, more particularly, to LED chips with light extraction films and related methods.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LEDs have been widely adopted in various illumination contexts, for backlighting of liquid crystal display (LCD) systems (e.g., as a substitute for cold cathode fluorescent lamps) and for direct-view LED displays. Applications utilizing LED arrays include vehicular headlamps, roadway illumination, light fixtures, and various indoor, outdoor, and specialty contexts. Desirable characteristics of LED devices include high luminous efficacy and long lifetime.

Typically, it is desirable to operate LEDs at the highest light emission efficiency possible, which can be measured by the emission intensity in relation to the output power. A practical goal to enhance emission efficiency is to maximize extraction of light emitted by the active region in the direction of the desired transmission of light. Light extraction and external quantum efficiency of an LED can be limited by a number of factors, including internal reflection. If photons are internally reflected in a repeated manner, then such photons will eventually be absorbed and never provide visible light that exits an LED. As LED applications continue to advance, challenges exist in producing high quality light with desired emission characteristics while also providing high light emission efficiency.

The art continues to seek improved LED array devices with small pixel pitches while overcoming limitations associated with conventional devices and production methods.

### SUMMARY

The present disclosure relates to light-emitting diode (LED) chips and, more particularly, to LED chips with light extraction films and related methods. Light extraction films include antireflective structures that are integrated within LED chip structures. Antireflective structures include one or more antireflective layers positioned to reduce internal reflections at various internal interfaces of LED chips. Certain LED chip structures include antireflective structures positioned between epitaxially grown active LED structures and carrier substrates on which the active LED structures are supported. Wafer level bonding sequences with one or more bonding layers are disclosed that facilitate integration of antireflective structures within LED chip structures.

In one aspect, an LED chip comprises: a substrate; an active LED structure on the substrate, the active LED structure comprising an n-type layer, a p-type layer, and an active layer between the n-type layer and the p-type layer; and an antireflective structure between the active LED structure and the substrate. The LED chip may further comprise a bonding layer between the active LED structure and the substrate. In certain embodiments, the bonding layer is between the antireflective structure and the substrate. In certain embodiments, the antireflective structure is between the bonding layer and the substrate. In certain embodiments, the antireflective structure is a single antireflective layer between the bonding layer and the substrate. In certain embodiments, a composition of the single antireflective layer is graded such that an index of refraction of the single antireflective layer is graded between the bonding layer and the substrate. In certain embodiments, the antireflective structure comprises a plurality of antireflective layers with index of refraction values that progressively decrease in a direction from the substrate toward the bonding layer. In certain embodiments, the antireflective structure is a first antireflective structure, and the LED chip further comprises a second antireflective structure, wherein the bonding is layer between the first and second antireflective structures. In certain embodiments, the antireflective structure comprises a first antireflective layer, a second antireflective layer, and a third antireflective layer, wherein the first and third antireflective layers have a first index of refraction, and the second antireflective layer has a second index of refraction that is different than the first index of refraction. In certain embodiments, the p-type layer is between the antireflective structure and the n-type layer. In certain embodiments, the n-type layer is between the antireflective structure and the p-type layer. In certain embodiments, the active LED structure comprises aluminum indium gallium phosphide (AlInGaP) and the substrate comprises sapphire. The LED chip may further comprise a p-contact and an n-contact that are both on a side of the active LED structure that is opposite the substrate. The LED chip may further comprise: at least one n-contact interconnect that extends through the p-type layer and the active layer to contact a portion of the n-type layer; a dielectric reflector layer on the p-type layer; a metal reflector layer on the dielectric reflector layer; and a plurality of reflective layer interconnects that extend from the metal reflector layer and through the dielectric reflector layer. In certain embodiments, a layer of the antireflective structure forms a bonding layer between the active LED structure and the substrate.

In another aspect, an LED chip comprises: a carrier substrate; a bonding layer on the carrier substrate; an active LED structure on the substrate such that the bonding layer is between the active LED structure and the carrier substrate, the active LED structure comprising an n-type layer, a p-type layer, and an active layer between the n-type layer and the p-type layer; a plurality of n-contact interconnects arranged to extend through the p-type layer and the active layer to contact a portion of the n-type layer; a dielectric reflector layer on the p-type layer; a metal reflector layer on the dielectric reflector layer; and a plurality of reflective layer interconnects that extend from the metal reflector layer and through the dielectric reflector layer to form an electrically conductive path to the p-type layer. In certain embodiments, the dielectric reflector layer, the metal reflector layer, and the plurality of reflective layer interconnects are on an opposite side of the active LED structure from the bonding layer. In certain embodiments, the active LED structure comprises aluminum indium gallium phosphide (AlInGaP) and the substrate comprises sapphire. The LED chip may further comprise a p-contact and an n-contact that are both on a side of the active LED structure that is opposite the carrier substrate. The LED chip may further comprise an antireflective structure between the active LED structure and the carrier substrate. In certain embodiments, the antireflective structure comprises a first antireflective layer, a second antireflective layer, and a third antireflective layer, wherein the first and third antireflective layers have a first index of refraction, and the second antireflective layer has a second index of refraction that is different than the first index of refraction. In certain embodiments, the bonding layer is part of the antireflective structure.

In another aspect, a method comprises: forming an active light-emitting diode (LED) structure on a growth substrate, the active LED structure comprising an n-type layer, a p-type layer, and an active layer between the n-type layer and the p-type layer; forming an antireflective structure; and bonding a carrier substrate to the active LED structure; and removing the growth substrate such that the antireflective structure is between the active LED structure and the carrier substrate. In certain embodiments, bonding the carrier substrate comprises forming a bonding layer between the antireflective layer and the carrier substrate. In certain embodiments, the bonding layer is formed by oxide-to-oxide fusion bonding. In certain embodiments, the active LED structure comprises aluminum indium gallium phosphide (AlInGaP) and the carrier substrate comprises sapphire. The method may further comprise: adhering the active LED structure to a temporary carrier before forming the antireflective layer; and removing the temporary carrier after bonding the carrier substrate to the active LED structure; wherein removing the growth substrate occurs before bonding the carrier substrate to the active LED structure.

In another aspect, a method comprises: forming an antireflective structure on a growth substrate; forming an active light-emitting diode (LED) structure on the antireflective structure and the growth substrate, the active LED structure comprising an n-type layer, a p-type layer, and an active layer between the n-type layer and the p-type layer; bonding a carrier substrate to the active LED structure and the antireflective layer; and removing the growth substrate such that the antireflective structure is between the active LED structure and the carrier substrate. In certain embodiments, bonding the carrier substrate comprises forming a bonding layer between the antireflective layer and the carrier substrate. In certain embodiments, the bonding layer is formed by oxide-to-oxide fusion bonding. In certain embodiments, the active LED structure comprises aluminum indium gallium phosphide (AlInGaP), and the antireflective layer comprises one or more of aluminum gallium arsenide (AlGaAs), aluminum arsenide (AlAs), aluminum phosphide (AlP), and gallium phosphide (GaP).

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-section of a light-emitting diode (LED) chip with an antireflective structure integrated within the LED chip according to principles of the present disclosure.

FIG. 2 is a cross-section of an LED chip that is a similar to the LED chip of FIG. 1 except the order of layers within the active LED structure is reversed.

FIG. 3A illustrates a fabrication step for forming the LED chip of FIG. 1 where an active LED structure and corresponding growth substrate are positioned for wafer bonding to another substrate.

FIG. 3B illustrates a fabrication step that follows FIG. 3A where bonding sublayers are joined together to form a bonding layer.

FIG. 3C illustrates a fabrication step that follows FIG. 3B where the growth substrate of FIG. 3B is removed.

FIG. 4A illustrates a fabrication step for forming the LED chip of FIG. 2 where an active LED structure and corresponding growth substrate are positioned to be adhered to a temporary carrier.

FIG. 4B illustrates a fabrication step that follows FIG. 4A where the active LED structure is adhered to the temporary carrier and the growth substrate of FIG. 4A is removed.

FIG. 4C illustrates a fabrication step that follows FIG. 4B where a bonding sublayer is formed on the substrate and another bonding sublayer is formed on the antireflective structure.

FIG. 4D illustrates a fabrication step that follows FIG. 4C where the bonding sublayers are joined together to form the bonding layer.

FIG. 4E illustrates a fabrication step that follows FIG. 4D where the temporary carrier of FIG. 4D is removed.

FIG. 5A illustrates a fabrication step in a sequence similar to FIGS. 4A to 4E except the antireflective structure is formed on the growth substrate before the active LED structure.

FIG. 5B illustrates a fabrication step that follows FIG. 5A where the active LED structure and the antireflective structure are adhered to the temporary carrier and the growth substrate of FIG. 5A is removed.

FIG. 5C illustrates a fabrication step that follows FIG. 5B where the bonding sublayer is formed on the substrate and the bonding sublayer is formed on the antireflective structure.

FIG. 5D illustrates a fabrication step that follows FIG. 5C where the bonding sublayers are joined together to form the bonding layer.

FIG. 5E illustrates a fabrication step that follows FIG. 5D where the temporary carrier of FIG. 5D is removed.

FIG. 6A illustrates a wafer level structure that is similar to the wafer level structure of FIG. 3A except the antireflective structure is formed on the carrier substrate before wafer level bonding to the active LED structure.

FIG. 6B illustrates the wafer level structure of FIG. 6A after bonding sublayers together to form the bonding layer and after the growth substrate is removed.

FIG. 7A illustrates a wafer level structure that is similar to the wafer level structure of FIG. 6A with the addition of a second antireflective structure.

FIG. 7B illustrates the wafer level structure of FIG. 7A after bonding sublayers together to form the bonding layer and after the growth substrate is removed.

FIG. 8 illustrates a portion of a wafer level structure where the antireflective structure is a single antireflective layer.

FIG. 9 illustrates a portion of a wafer level structure where the antireflective structure includes multiple antireflective layers with index of refraction values that progressively increase or decrease.

FIG. 10 illustrates a portion of a wafer level structure where the antireflective structure includes a larger number of antireflective layers than illustrated in previous embodiments.

FIG. 11 illustrates a portion of a wafer level structure wherein the antireflective structure comprises a single layer with a graded composition.

FIG. 12 is a cross-section of an LED chip that is similar to the LED chips of FIGS. 1 and 2 and further includes improved current spreading and internal reflective structures.

FIG. 13 is a cross-section of an LED chip that is similar to the LED chip of FIG. 12 and further includes an antireflective structure.

FIG. 14 is a partial top view illustration of a layout for reflective layer interconnects relative to n-type interconnects that may be implemented in the LED chips of FIGS. 12 and 13.

FIG. 15 is a general cross-section of an LED chip that is similar to the LED chip of FIG. 12 and further includes light extraction features on a surface of the substrate that forms an interface with the bonding layer.

FIG. 16 is a general cross-section of an LED chip that is similar to the LED chip of FIG. 15 and further includes the antireflective structure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) chips and, more particularly, to LED chips with light extraction films and related methods. Light extraction films include antireflective structures that are integrated within LED chip structures. Antireflective structures include one or more antireflective layers positioned to reduce internal reflections at various internal interfaces of LED chips. Certain LED chip structures include antireflective structures positioned between epitaxially grown active LED structures and carrier substrates on which the active LED structures are supported. Wafer level bonding sequences with one or more bonding layers are disclosed that facilitate integration of antireflective structures within LED chip structures.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials and other Group III-V systems such as gallium phosphide (GaP), aluminum indium gallium phosphide (AlInGaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range in a range of 430 nanometers (nm) to 480 nm. In other embodiments, the active LED structure emits green light with a peak wavelength in a range of 500 nm to 570 nm. In other embodiments, the active LED structure emits orange and/or red light with a peak wavelength range of 600 nm to 700 nm. In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. Near-IR and/or IR wavelengths for LED structures of the present disclosure may have wavelengths above 700 nm, such as in a range from 700 nm to 1000 nm, or more.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. In certain embodiments, a passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as flip-chip and/or vertical geometries. A flip-chip geometry may include a structure where anode and cathode connections are made from a same side of the LED chip in order to facilitate flip-chip mounting to another surface. A vertical geometry may include a structure where anode and cathode connections on opposing sides or faces of the LED chip.

In certain embodiments of the present disclosure, an antireflective structure with one or more antireflective layers is integrated within LED chip structures to provide enhanced light extraction and/or to alter emission angles or patterns of light exiting LED chip structures. Antireflective structures may be positioned between active LED structures and carrier substrates in LED chips. In certain aspects, a carrier substrate may be used to differentiate from a growth substrate in LED chips. In this regard, a growth substrate may refer to a substrate on which an active LED structure is epitaxially grown, and a carrier substrate may refer to a different substrate that mechanically supports the active LED structure after removal of the growth substrate. In certain embodiments, the one or more antireflective layers are provided at or near a wafer bonding interface that facilitates addition of a carrier substrate and removal of a growth substrate for a particular active LED structure. The one or more antireflective layers may embody insulating layers that are deposited on an active LED structure in a separate growth system that is used for epitaxial deposition of the active LED structure. In other embodiments, one or more antireflective layers may embody epitaxial layers that are grown in a same growth system as the active LED structure.

As used herein, an antireflective layer or coating may include one or more layers that provide an index of refraction that is selected to reduce the reflection or refraction of light at an interface thereof. In certain embodiments, antireflective layers as disclosed herein may comprise single or multiple thin layers that transition from the index of refraction of one side of the interface to the other. In this regard, an antireflective layer may provide a graded index of refraction with values in a range between a first index of refraction associated with a first medium on one side of the interface and a second index of refraction associated with a second medium that is on the other side of the interface. In certain embodiments, an antireflective layer may include multiple layers that alternate in composition and index of refraction. Advantageously, by using the antireflective layer to transition between the different mediums, abrupt index of refraction changes may be avoided, which may reduce the amount of light reflected internally at the interface. Additionally, the one or more antireflective layers may also be configured to control and/or tailor emission angles of light exiting LED chips. For example, the one or more antireflective layers may be configured to focus emissions along narrower emission angles for use in directional LED applications. Antireflective layers may include many different materials, including but not limited to one or more oxides of silicon (e.g., SiO₂), oxides of zirconium (e.g., ZrO₂), oxides of aluminum (e.g., Al₂O₃), oxides of titanium (e.g., TiO₂, Ti₃O₅), oxides of tantalum (e.g., Ta₂O₅), oxides of indium (e.g., In₂O₃), indium tin oxide (ITO), silicon nitride (e.g., SiNₓ), magnesium fluoride (e.g., MgF₂), cerium fluoride (e.g., CeF₃), fluoropolymers, and combinations thereof. In still further embodiments, antireflective layers may include epitaxial layers, such as combinations of aluminum gallium arsenide (AlGaAs) and aluminum arsenide (AlAs) and/or combinations of aluminum phosphide (AlP) and GaP. In such embodiments, the antireflective layers may be epitaxially grown in a same growth system as an active LED structure of an LED chip. Relative thicknesses of antireflective layers or sub-layers within a multi-layer antireflective structure may comprise one or more combinations of quarter-wavelength and half-wavelength values of target light, for example, the wavelength of light emitted by an LED chip and/or a wavelength of light provided by lumiphoric materials. Specific arrangements of antireflective layers or coatings in LED chips are disclosed that may provide a general reduction in the rate of total internal reflection at various internal interfaces, thereby improving the overall brightness of the LED chips.

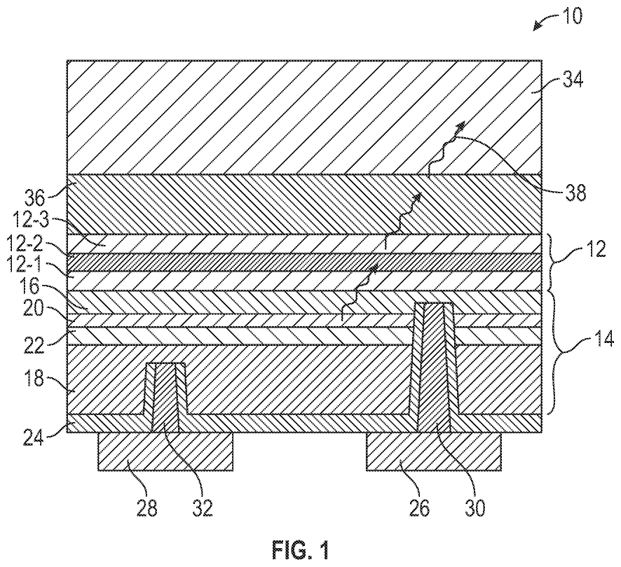

FIG. 1 is a cross-section of an LED chip 10 with an antireflective structure 12 integrated within the LED chip 10 according to principles of the present disclosure. The LED chip 10 includes an active LED structure 14, which may also be referred to as an epitaxial layer structure, comprising a p-type layer 16, an n-type layer 18, and an active layer 20 therebetween. For illustrative purposes, another p-type layer 22, such as a p-type cladding layer, is illustrated adjacent to the active layer 20. As described above, the active LED structure 14 may include many additional layers and/or sublayers such as one or more buffer layers, nucleation layers, super lattice structures, undoped layers, cladding layers, contact layers, and current-spreading layers and light extraction layers and elements. The active layer 20 may comprise a single quantum well or a multiple quantum well, among other structures.

A passivation layer 24 may be included on the active LED structure 14 to provide electrical insulation for portions of the LED chip 10 relative to electrical connections. The passivation layer 24 may comprise various insulating and/or dielectric materials. In certain embodiments, the passivation layer 24 is a single layer, and in other embodiments, the passivation layer 24 comprises a plurality of layers. Suitable materials for the passivation layer 24 include but are not limited to SiO₂ and/or SiN. The electrical connections are provided by a p-contact 26 and an n-contact 28 that are arranged on the passivation layer 24. The p-contact 26, which may also be referred to as an anode contact, may comprise one or more p-contact interconnects 30 that extend through the passivation layer 24 to provide an electrical path to the p-type layer 16. The one or more p-contact interconnects 30 may be referred to as p-contact vias. The n-contact 28, which may also be referred to as a cathode contact, may comprise one or more n-contact interconnects 32 that extend through the passivation layer 24 to provide an electrical path to the n-type layer 18. The one or more n-contact interconnects 32 may be referred to as n-contact vias. In operation, a signal applied across the p-contact 26 and the n-contact 28 is conducted to the p-type layer 16 and the n-type layer 18, causing the LED chip 10 to generate light from the active layer 20. The p-contact 26 and the n-contact 28 may comprise many different materials such as Au, copper (Cu), nickel (Ni), In, Al, Ag, tin (Sn), Pt, or combinations thereof.

The active LED structure 14 is provided on a substrate 34. For flip-chip embodiments, the substrate 34 may comprise a material that is light-transmissive and/or light-transparent to wavelengths generated by the active LED structure 14. By way of example, the substrate 34 may comprise sapphire or glass in certain embodiments. Depending on the application, the active LED structure 14 may be configured to provide a wavelength in any number of ranges, such as blue, green, red, other portions of the visible spectrum, the UV spectrum, or the IR spectrum. As described above, materials systems vary based on the intended wavelength. In certain embodiments, a native growth substrate used for a particular materials system may not exhibit suitable light-transmissive and/or light-transparent properties for the intended emission wavelength. For example, in the context of yellow and/or red wavelengths, the active LED structure 14 may comprise AlInGaP materials grown on a native growth substrate of GaAs. However, GaAs may be too light-absorbing for yellow and/or red wavelengths. Additionally, an index of refraction for GaAs is relatively high such that only narrow emission escape cones are provided and large portions of light may be internally reflected.

According to principles of the present disclosure, the growth substrate may be removed and replaced with the substrate 34 in FIG. 1. In this manner, the substrate 34 is not a growth substrate for the active LED structure 14, but rather is a carrier substrate that is attached to the active LED structure 14. The substrate 34 may comprise a material, such as sapphire or glass, with a lower index of refraction and/or increased light-transmissivity as compared with the growth substrate. As illustrated, a bonding layer 36 may be provided between the active LED structure 14 and the substrate 34 to facilitate bonding therebetween. The bonding layer 36 may be formed by direct wafer bonding techniques, such as oxide-oxide fusion bonding. By way of example, the bonding layer 36 may comprise SiO₂ formed by oxide-oxide fusion for bonding the active LED structure 14 to the substrate 34. The orientation of the active LED structure 14 may be controlled based on the fabrication sequence for transferring from the growth substrate to the substrate 34 of FIG. 1. In the example of FIG. 1, the p-type layer 16 is positioned closest to the antireflective structure 12 such that the p-type layer 16 is between the antireflective structure 12 and the n-type layer 18. This may be advantageous for applications where the p-type layer 16 has a reduced thickness relative to the n-type layer 18, thereby positioning the active layer 20 closer to the antireflective layer 12 and substrate 34. As mentioned above, it is understood the relative dimensions in FIG. 1 are not necessarily drawn to scale.

In the flip-chip configuration of FIG. 1, the substrate 34 that is bonded to the active LED structure 14 forms a light-emitting top surface of the LED chip 10. When electrically activated, light 38 that is generated in the active layer 20 may propagate through the antireflective structure 12, the bonding layer 36, and ultimately through the substrate 34 before being emitted from the LED chip 10. As mentioned above, the bonding layer 36 facilitates wafer transfer so that the growth substrate may be removed. However, the presence of the bonding layer 36 and the materials used (e.g., oxide-oxide fusion bonding) may provide an index of refraction step that causes undesirable internal reflection. In this regard, the antireflective structure 12 is configured to reduce internal reflections at interfaces with the bonding layer 36 and also with the active LED structure 14, thereby increasing light extraction for the light 38 to escape the LED chip 10. For illustrative purposes, the antireflective structure 12 is shown with three antireflective layers 12-1 to 12-3, although many other layer structures are possible for reducing internal reflections depending on the particular embodiment. In the example illustrated in FIG. 1, the antireflective layers 12-1 to 12-3 may alternate in composition and index of refraction such that the antireflective layers 12-1 and 12-3 have a same index of refraction that is different than an index of refraction of the middle antireflective layer 12-2. As indicated above, in certain embodiments, the bonding layer 36 may comprise a material that is the same or similar to layers of the antireflective structure 12. In this regard, the bonding layer 36 may be formed as part of the antireflective structure 12 in certain embodiments. For example, controlled growth and/or polishing of the bonding layer 36 may provide a sufficient thickness for the bonding layer 36 to provide an index of refraction step that forms one or more sublayers of the antireflective structure 12.

While the LED chip 10 is shown in a flip-chip configuration, the principles described for the integrated antireflective structure 12 are applicable to other LED chip structures.

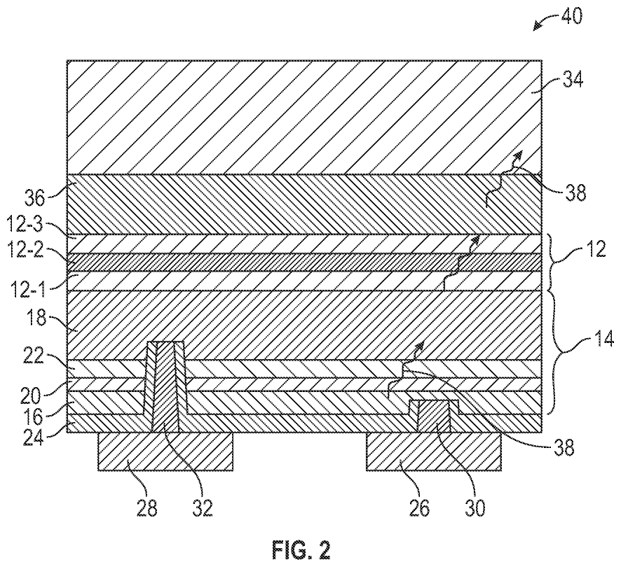

FIG. 2 is a cross-section of an LED chip 40 that is a similar to the LED chip 10 except the order of layers within the active LED structure 14 is reversed. In this manner, the n-type layer 18 is positioned closest to the antireflective structure 12 and the substrate 34. As mentioned with respect to FIG. 1, the orientation of the active LED structure 14 may be controlled based on the fabrication sequence for transferring from the growth substrate to the substrate 34. In the example of FIG. 2, the p-type layer 16 is closest to the mounting surface where the p-contact 26 and the n-contact 28 reside. For embodiments where the p-type layer 16 is thinner than the n-type layer 18, the p-contact interconnects 30 and the n-contact interconnects 32 may have less distances to travel within the active LED structure 14. It is understood the relative dimensions in FIG. 2 are not necessarily drawn to scale.

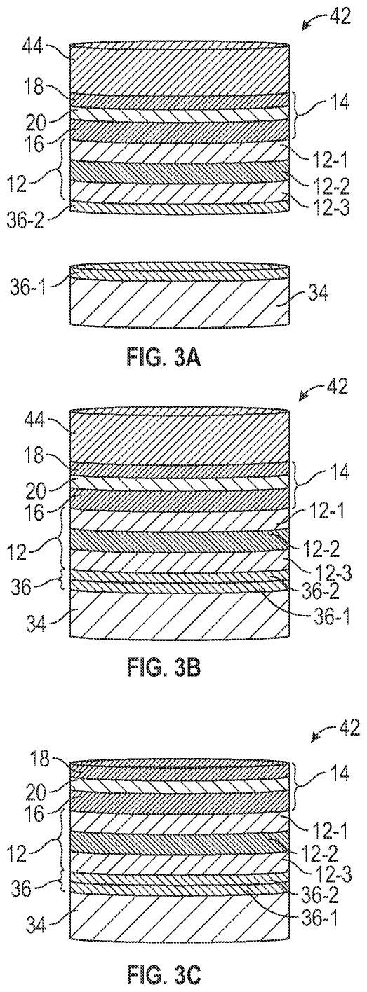

FIGS. 3A to 3C illustrate a wafer level fabrication sequence for a wafer level structure 42 that may be used for forming the LED chip 10 of FIG. 1. In FIGS. 3A to 3A, each element is shown at a wafer level before individual LED chips (e.g., FIG. 1) are singulated from the wafer level structure 42.

FIG. 3A illustrates a fabrication step for forming the LED chip 10 of FIG. 1 where the active LED structure 14 and corresponding growth substrate 44 are positioned for wafer bonding to the substrate 34. In this regard, the growth substrate 44 is selected with a material type and crystal structure that facilitates epitaxial growth of the active LED structure 14. The antireflective structure 12 is formed on the active LED structure 14 and more specifically on the p-type layer 16. In FIG. 3A, the bonding layer 36 is split into two bonding sublayers 36-1, 36-2. The bonding sublayer 36-1 is formed on the substrate 34 and the bonding sublayer 36-2 is formed on the antireflective structure 12. In the orientation illustrated in FIG. 3A, the bonding sublayers 36-1, 36-2 are positioned to facilitate the wafer bonding.

FIG. 3B illustrates a fabrication step that follows FIG. 3A where the bonding sublayers 36-1, 36-2 are joined together to form the bonding layer 36. As described above, certain embodiments relate to the bonding sublayers 36-1, 36-2 being joined together by oxide-to-oxide fusion bonding. In this regard, the subsequent bonding layer 36 is mechanically robust for securing the substrate 34 to the growth substrate 44, the active LED structure 14, and the antireflective structure 12.

FIG. 3C illustrates a fabrication step that follows FIG. 3B where the growth substrate 44 of FIG. 3B is removed. The passivation layer 24, the p-contact interconnects 30, the p-contact 26, the n-contact interconnects 32, and the n-contact 28 of FIG. 1 may be formed across the wafer level structure 42 in an arrangement as illustrated in FIG. 1. The waver level structure 42 may then be singulated to form a plurality of the LED chips 10 as illustrated in FIG. 1. In this configuration, the p-type layer 16 is between the antireflective structure 12 and the n-type layer 18.

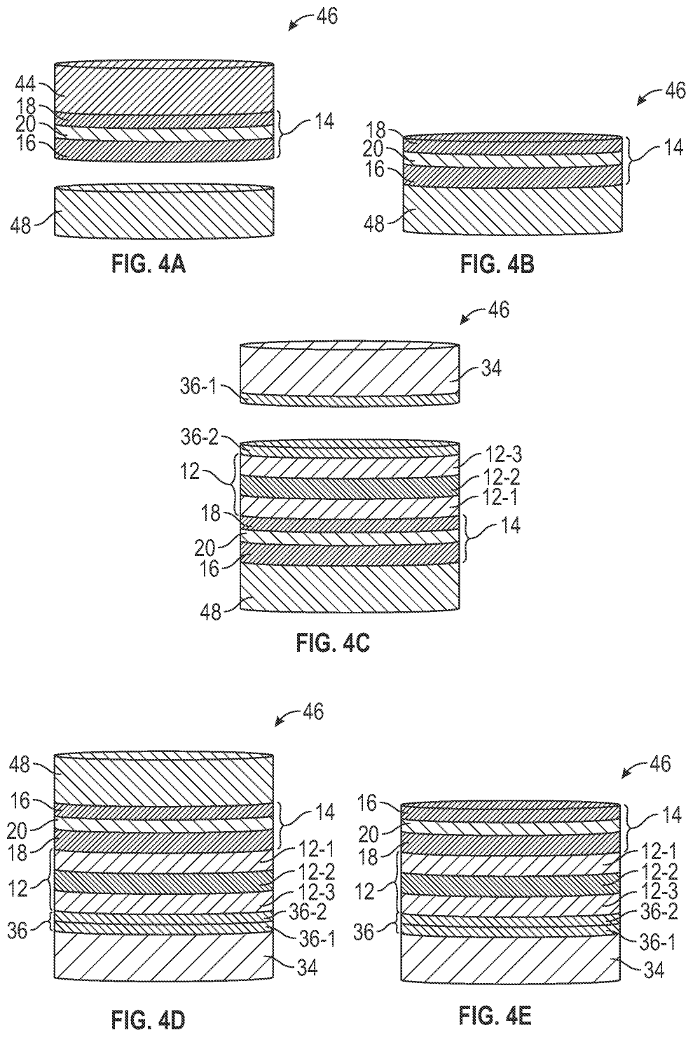

FIGS. 4A to 4E illustrate a wafer level fabrication sequence for a wafer level structure 46 that may be used for forming the LED chip 40 of FIG. 2. In FIGS. 4A to 4E, each element is shown at a wafer level before individual LED chips (e.g., FIG. 2) are singulated from the wafer level structure 46.

FIG. 4A illustrates a fabrication step for forming the LED chip 40 of FIG. 2 where the active LED structure 14 and corresponding growth substrate 44 are positioned to be adhered to a temporary carrier 48. The temporary carrier 48 may embody a wafer or substrate of any material capable of supporting the active LED structure 14 during subsequent removal of the growth substrate 44. In certain embodiments, the temporary carrier 48 comprises silicon or a silicon wafer.

FIG. 4B illustrates a fabrication step that follows FIG. 4A where the active LED structure 14 is adhered to the temporary carrier 48 and the growth substrate 44 of FIG. 4A is removed.

FIG. 4C illustrates a fabrication step that follows FIG. 4B where the bonding sublayer 36-1 is formed on the substrate 34 and the bonding sublayer 36-2 is formed on the antireflective structure 12. The antireflective structure 12 is formed on the active LED structure 14 and more specifically on the n-type layer 18. As with the embodiments described above for FIG. 3A, the bonding sublayers 36-1, 36-2 are positioned to facilitate oxide-to-oxide fusion bonding in a subsequent step.

FIG. 4D illustrates a fabrication step that follows FIG. 4C where the bonding sublayers 36-1, 36-2 are joined together to form the bonding layer 36. In certain embodiments, the wafer level structure 46 may be oriented such that the temporary carrier 48 is positioned up to facilitate removal of the temporary carrier 48. In alternative removal steps, the temporary carrier 48 may be positioned down for removal.

FIG. 4E illustrates a fabrication step that follows FIG. 4D where the temporary carrier 48 of FIG. 4D is removed. The passivation layer 24, the p-contact interconnects 30, the p-contact 26, the n-contact interconnects 32, and the n-contact 28 of FIG. 2 may be formed across the wafer level structure 46 in an arrangement as illustrated in FIG. 2. The wafer level structure 46 may then be singulated to form a plurality of the LED chips 40 as illustrated in FIG. 2. By using the temporary carrier 48 as illustrated in FIGS. 4A to 4D, the n-type layer 18 is between the antireflective structure 12 and the p-type layer 16.

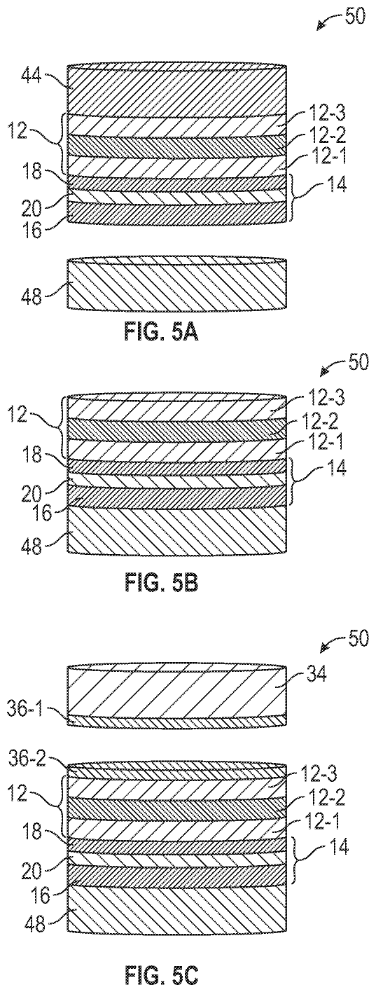

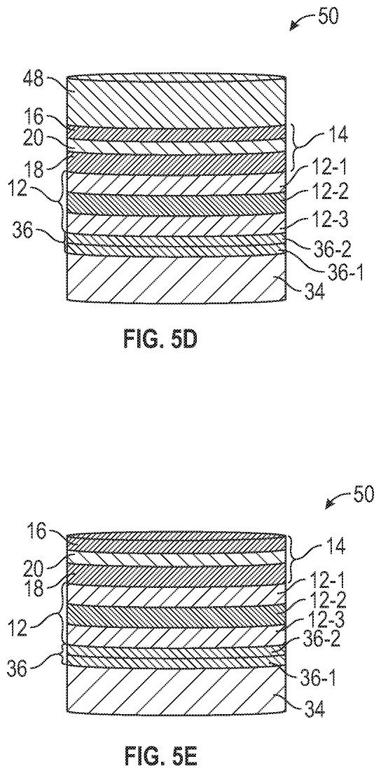

FIGS. 5A to 5E illustrate a wafer level fabrication sequence for a wafer level structure 50 that is similar to the wafer level structure 46 of FIGS. 4A to 4E except the antireflective structure 12 is formed on the growth substrate 44 before the active LED structure 14. In this regard, the antireflective structure 12 may be epitaxially grown in a same growth chamber as the active LED structure 14 in certain embodiments. In the example where the active LED structure comprises AlInGaP-based materials, the growth substrate 44 may comprise GaAs. In such examples, the antireflective structure 12 may comprise combinations of AlGaAs and AlAs and/or combinations of AIP and GaP for the antireflective layers 12-1 to 12-3.

FIG. 5B illustrates a fabrication step that follows FIG. 5A where the active LED structure 14 and the antireflective structure 12 are adhered to the temporary carrier 48 and the growth substrate 44 of FIG. 5A is removed.

FIG. 5C illustrates a fabrication step that follows FIG. 5B where the bonding sublayer 36-1 is formed on the substrate 34 and the bonding sublayer 36-2 is formed on the antireflective structure 12. As with the embodiments described above for FIG. 3A, the bonding sublayers 36-1, 36-2 are positioned to facilitate oxide-to-oxide fusion bonding in a subsequent step.

FIG. 5D illustrates a fabrication step that follows FIG. 5C where the bonding sublayers 36-1, 36-2 are joined together to form the bonding layer 36. In certain embodiments, the wafer level structure 50 may be oriented such that the temporary carrier 48 is positioned up to facilitate removal of the temporary carrier 48. In alternative removal steps, the temporary carrier 48 may be positioned down for removal.

FIG. 5E illustrates a fabrication step that follows FIG. 5D where the temporary carrier 48 of FIG. 5D is removed. The passivation layer 24, the p-contact interconnects 30, the p-contact 26, the n-contact interconnects 32, and the n-contact 28 of FIG. 2 may be formed across the wafer level structure 50 in an arrangement as illustrated in FIG. 2. The wafer level structure 50 may then be singulated. By forming the antireflective structure 12 before the active LED structure as described for FIG. 5A, the n-type layer 18 is positioned between the antireflective structure 12 and the p-type layer 16.

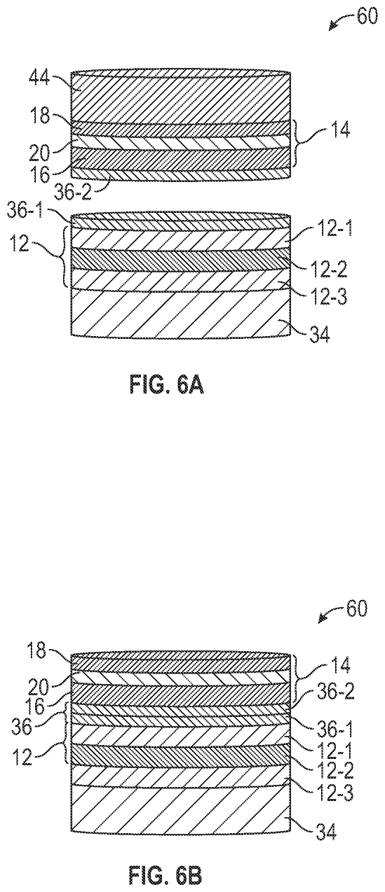

FIG. 6A illustrates a wafer level structure 60 that is similar to the wafer level structure 42 of FIG. 3A except the antireflective structure 12 is formed on the substrate 34 before wafer level bonding to the active LED structure 14. FIG. 6B illustrates the wafer level structure 60 of FIG. 6A after bonding sublayers 36-1, 36-2 together to form the bonding layer 36 and after the growth substrate 44 is removed. Aside from the position of the antireflective structure 12, the wafer level structure 60 of FIG. 6B may be fabricated in a similar manner as described above for FIGS. 3A to 3C. As illustrated in FIG. 6B, the bonding layer 36 is positioned between the substrate 34 and the active LED structure 14. As with other embodiments, further fabrication of the passivation layer 24, the p-contact interconnects 30, the p-contact 26, the n-contact interconnects 32, and the n-contact 28 may follow and individual LED chips may be singulated in a manner similar to FIGS. 1 and 2.

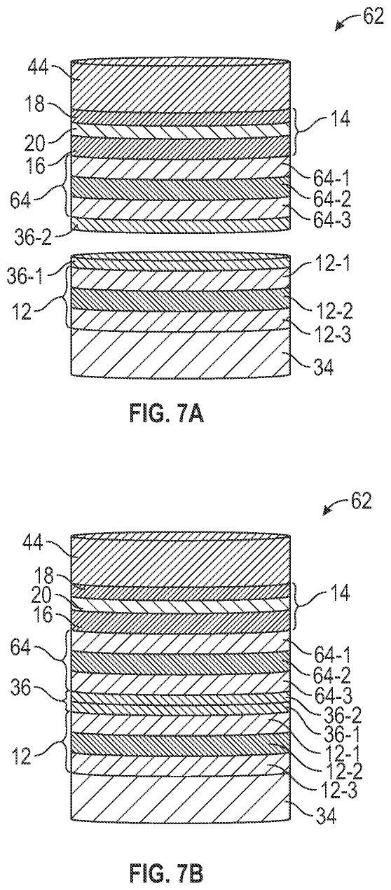

FIG. 7A illustrates a wafer level structure 62 that is similar to the wafer level structure 60 of FIG. 6A with the addition of a second antireflective structure 64. In this regard, the antireflective structure 12 may be referred to as a first antireflective structure 12. As illustrated, the first antireflective structure 12 may be positioned on the substrate 34 before wafer bonding, and the second antireflective structure 64 may be positioned on the active LED structure 14 before wafer bonding. In certain embodiments, the second antireflective structure 64 may comprise antireflective sublayers 64-1 to 64-3 in a similar manner as described above for the first antireflective structure 12. FIG. 7B illustrates the wafer level structure 62 of FIG. 7A after bonding the sublayers 36-1, 36-2 together to form the bonding layer 36 and after the growth substrate 44 is removed. As illustrated, the bonding layer 36 is positioned between the first and second antireflective structures 12, 64. As with other embodiments, further fabrication of the passivation layer 24, the p-contact interconnects 30, the p-contact 26, the n-contact interconnects 32, and the n-contact 28 may follow and individual LED chips may be singulated in a manner similar to FIGS. 1 and 2.

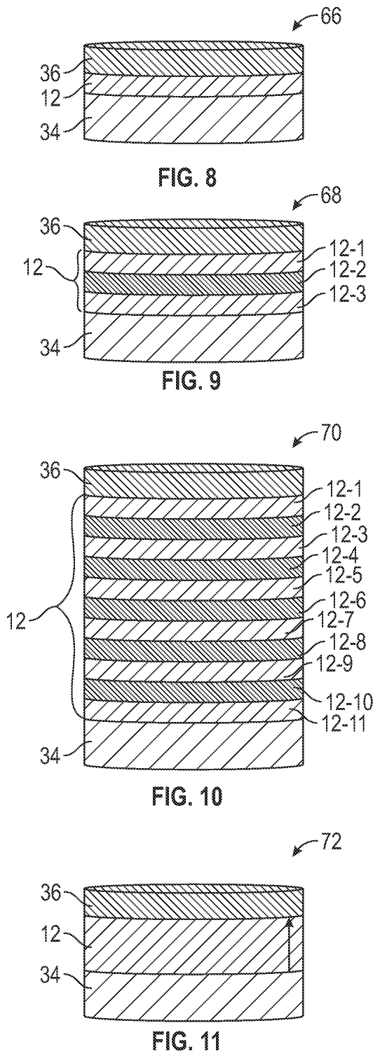

FIG. 8 illustrates a portion of a wafer level structure 66 where the antireflective structure 12 is a single antireflective layer. In such embodiments, the antireflective layer may have an index of refraction that is intermediate the index of refractions of the next-adjacent layers. In the example of FIG. 8, the antireflective structure 12 forms opposing interfaces with the substrate 34 and the bonding layer 36. Accordingly, the antireflective structure 12 may embody a single layer with an index of refraction that is intermediate the substrate 34 and the bonding layer 36. The single layer embodiment for the antireflective structure 12 of FIG. 8 may be implemented in any of the previous embodiments, including FIGS. 1 to 7B.

FIG. 9 illustrates a portion of a wafer level structure 68 where the antireflective structure 12 includes multiple antireflective layers 12-1 to 12-3 with index of refraction values that progressively increase or decrease. In certain embodiments, the bonding layer 36 may have a lower index of refraction than the substrate 34, and the index of refraction values may progressively decrease from the substrate 34 to the bonding layer 36 for improved light extraction. For example, the bonding layer 12-3 forms an interface with the substrate 34 and may have a highest index of refraction within the antireflective structure 12, while the index of refraction values for each successive antireflective layer 12-2, 12-1 may progressively decrease. In certain embodiments, each layer of the antireflective layers 12-1 to 12-3 may have compositionally different materials. For example, in the context of SiO₂ for the bonding layer 36 and sapphire for the substrate 34, the antireflective layer 12-3 may comprise TiO₂, the antireflective layer 12-2 may comprise SiN, and the antireflective layer 12-1 may comprise SiO₂. The multiple layer embodiment of FIG. 9 for the antireflective structure 12 may be implemented in any of the previous embodiments, including FIGS. 1 to 7B.

FIG. 10 illustrates a portion of a wafer level structure 70 where the antireflective structure 12 includes a larger number of antireflective layers than illustrated in previous embodiments. By way of example, the antireflective structure 12 of FIG. 10 is illustrated with eleven antireflective layers 12-1 to 12-11. It is understood the principles described are applicable for various numbers of antireflective layers depending on the embodiment and manufacturing capabilities. In certain embodiments, the index of refraction values may alternate between two or three values within the antireflective structure 12. For example, the odd numbered antireflective layers 12-1, 12-3, 12-5, 12-7, 12-9, and 12-11 may have a first index of refraction that is different than an index of refraction of the even numbered antireflective layers 12-2, 12-4, 12-6, 12-8, and 12-10. The multiple layer embodiment of FIG. 10 for the antireflective structure 12 may be implemented in any of the previous embodiments, including FIGS. 1 to 7B.

FIG. 11 illustrates a portion of a wafer level structure 72 wherein the antireflective structure 12 comprises a single layer with a graded composition. In this manner the antireflective structure 12 may embody a single layer with an index of refraction that is progressively graded between the index of refractions of the next-adjacent layers. In the example of FIG. 11, the antireflective structure 12 forms opposing interfaces with the substrate 34 and the bonding layer 36. Accordingly, a composition of the single layer of the antireflective structure 12 may be graded so that the index of refraction is graded in a direction from the substrate 34 to the bonding layer 36 as illustrated by the superimposed arrow in FIG. 11. For embodiments where the substrate 34 has a higher index of refraction than the bonding layer 36, the index of refraction within the single layer of the antireflective structure 12 may progressively decrease in the direction of the arrow in FIG. 11. In the context of SiO₂ for the bonding layer 36 and sapphire for the substrate 34, the composition of the single layer of the antireflective structure 12 may be graded from SiN adjacent the substrate 34 to SiO₂ adjacent the bonding layer 36 with various compositions of SiON therebetween. The single layer embodiment for the antireflective structure 12 of FIG. 11 may be implemented in any of the previous embodiments, including FIGS. 1 to 7B.

The principles of the present disclosure are applicable to high power and/or large area LED chips. In this regard, LED chips according to the present disclosure may be selected with larger dimensions and/or increased current densities. For example, larger dimensions may include an LED chip having a smallest lateral dimension that is at least 500 microns (μm), or in a range from at least 500 μm to 2000 μm, or in a range from at least 500 μm to 1000 μm, or in a range from at least 1000 μm to 2000 μm. Exemplary LED chip sizes for high-power applications with generally square shapes may include 500 μm by 500 μm, or 1000 μm by 1000 μm, or 2000 μm by 2000 μm with tolerances of ±10% from any of the above-specified values. In other embodiments, exemplary LED chips may have rectangular shapes with any of the above-specified smallest lateral dimensions and with tolerances of ±10% from any of the specified values. In addition, the principles of the present disclosure may also be applicable to other LED chip sizes, including smallest lateral dimensions as low as 50 μm, or in a range from 50 μm to any of the above specified larger values, such as 50 μm to 300 μm. In such embodiments, smaller chip sizes at or near 50 μm may still be used for high-power applications by arranging multiple ones of the smaller chips together in regions and/or subregions to provide a high-power device.

In the context of LED chips with substrate transfer, such as red emitting active LED structures on sapphire carrier substrates, the principles of the present disclosure advantageously provide flip-chip LED structures with improved current spreading capabilities and improved internal reflective structures.

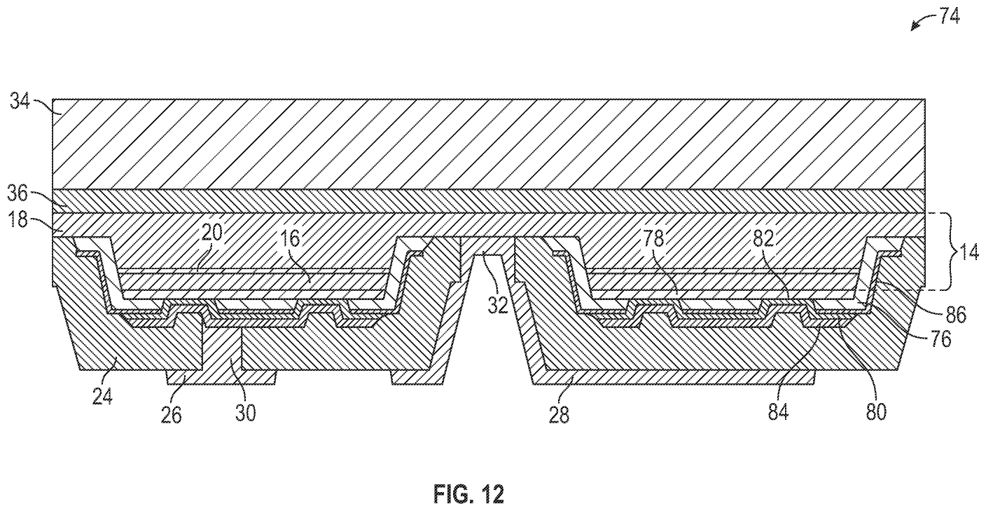

FIG. 12 is a cross-section of an LED chip 74 that is similar to the LED chips 10, 40 of FIGS. 1 and 2 and further includes improved current spreading and internal reflective structures. As illustrated, the LED chip 74 includes the bonding layer 36 that is between the substrate 34 and the active LED structure 14 as previously described. The LED chip 74 further includes a first reflective layer 76 that is provided on portions of the p-type layer 16 with a current spreading layer 78 therebetween. The first reflective layer 76 may comprise many different materials and preferably comprises a material that presents an index of refraction step with the material of the active LED structure 14 to promote total internal reflection (TIR) of light generated from the active LED structure 14. For example, the first reflective layer 76 may comprise a material with an index of refraction lower than the index of refraction of the active LED structure 14. In certain embodiments, the first reflective layer 76 comprises a dielectric material, with some embodiments comprising SiO₂ and/or SiN. It is understood that many dielectric materials can be used such as SiN, SiN_{X}, Si₃N₄, Si, germanium (Ge), SiO₂, SiO_{X}, titanium dioxide (TiO₂), tantalum pentoxide (Ta₂O₅), ITO, magnesium oxide (MgO_{X}), zinc oxide (ZnO), and combinations thereof. Accordingly, the first reflective layer 76 may be referred to as a dielectric reflector layer and/or a dielectric reflective layer. In certain embodiments, the first reflective layer 76 may include multiple alternating layers of different dielectric materials, e.g., alternating layers of SiO₂ and SiN that symmetrically repeat or are asymmetrically arranged. The first reflective layer 76 may have different thicknesses depending on the type of materials used, with some embodiments having a thickness of at least 0.2 microns (μm). The first reflective layer 76 may have a thickness in the range of 0.2 μm to 0.7 μm, while in some of these embodiments the thickness can be approximately 0.5 μm. Portions of the first reflective layer 76 may extend along mesa sidewalls of the active LED structure 14 and along sidewall portions of the p-type layer 16, the active layer 20, and the n-type layer 18. The current spreading layer 78 may embody a layer of conductive material, for example a transparent conductive oxide such as indium tin oxide (ITO) or a metal such as platinum (Pt), although other materials may be used.

The LED chip 74 may further include a second reflective layer 80 that is on the first reflective layer 76 such that the first reflective layer 76 is between the active LED structure 14 and the second reflective layer 80. The second reflective layer 80 may include a metal layer that is configured to reflect any light from the active LED structure 14 that may pass through the first reflective layer 76. The second reflective layer 80 may comprise many different materials such as Ag, gold (Au), or combinations thereof. Accordingly, the second reflective layer 80 may be referred to as a metal reflector layer and/or a metal reflective layer. As illustrated, the second reflective layer 80 may include one or more reflective layer interconnects 82 that provide electrically conductive paths through the first reflective layer 76 to the current spreading layer 78. In certain embodiments, the reflective layer interconnects 82 comprise reflective layer vias. Accordingly, the first reflective layer 76, the second reflective layer 80, and the reflective layer interconnects 82 form a reflective structure integrated within the LED chip 74 that effectively redirects downward propagating light toward the bonding layer 36 and substrate 34.

The LED chip 74 may also include a barrier layer 84 on a side of the second reflective layer 80 opposite the first reflective layer 76 to prevent migration of the second reflective layer 80 material, such as Ag, to other layers. Preventing this migration helps the LED chip 74 maintain efficient operation throughout its lifetime. The barrier layer 84 may comprise an electrically conductive material, with suitable materials including but not limited to sputtered Ti/Pt followed by evaporated Au bulk material or sputtered Ti/Ni followed by an evaporated Ti/Au bulk material. In certain embodiments, an adhesion layer 86 may be positioned at one or more interfaces between the first reflective layer 76 and the second reflective layer 80 to promote improved adhesion therebetween. Many different materials can be used for the adhesion layer 86, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlₓO_{y}. In certain embodiments, the adhesion layer 86 comprises AlₓO_{y}, where 1≤x≤4 and 1≤y≤6. In certain embodiments, the adhesion layer comprises AlₓO_{y}, where x=2 and y=3, or Al₂O₃. The adhesion layer 86 may be deposited by electron beam deposition that may provide a smooth, dense, and continuous layer without notable variations in surface morphology. The adhesion layer 86 may also be deposited by sputtering, chemical vapor deposition, or plasma enhanced chemical vapor deposition.

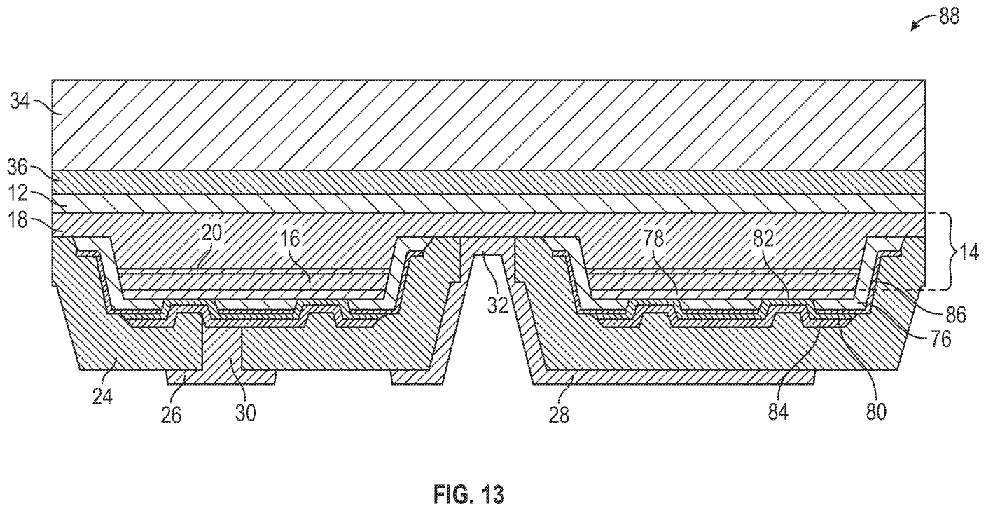

FIG. 13 is a cross-section of an LED chip 88 that is similar to the LED chip 74 of FIG. 12 and further includes the antireflective structure 12. The antireflective structure 12 may be positioned between the active LED structure 14 and the bonding layer 36. In this regard, light from the active layer 20 that propagates downward may be redirected by the internal reflective structure formed by the first reflective layer 76, the second reflective layer 80, and the reflective layer interconnects 82. Such redirected light may then propagate through the active LED structure 14, and the antireflective structure 12 provides increased light extraction for light to pass through the bonding layer 36 and ultimately out of the substrate 34. The antireflective structure 12 of FIG. 13 may be implemented according to any of the previous embodiments, including FIGS. 1 to 11.

For illustrative purposes, a single n-contact interconnect 32 and several reflective layer interconnects 82 are shown in the views of FIGS. 12 and 13. In practice, the LED chip 74 may include a plurality of the n-contact interconnects 32 spaced apart across the active LED structure 14 and any number of reflective layer interconnects 82 may be positioned between adjacent n-contact interconnects 32.

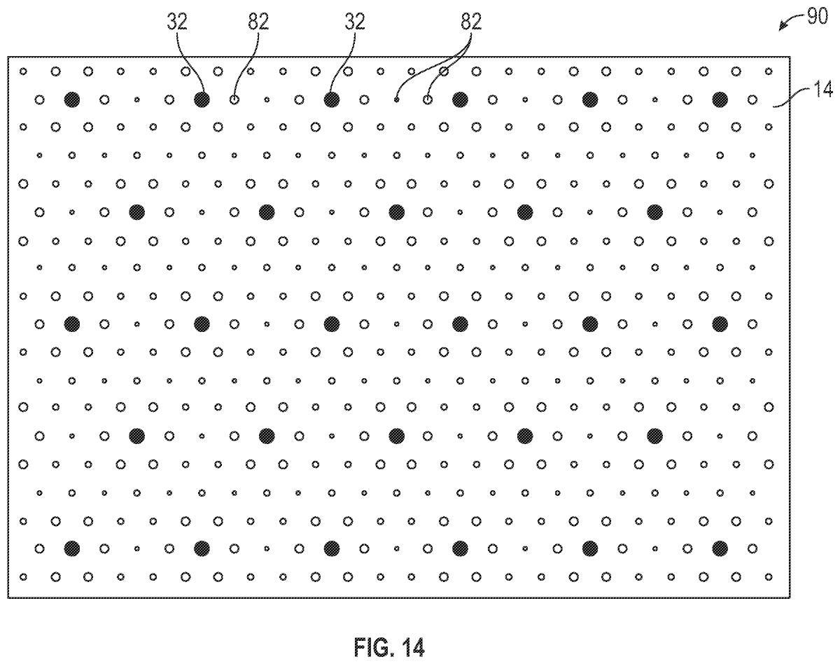

FIG. 14 is a partial top view illustration of a layout 90 for reflective layer interconnects 82 relative to n-contact interconnects 32 that may be implemented in the LED chips of FIGS. 12 and 13. As illustrated, the n-contact interconnects 32 are arranged in an array across the active LED structure 14 where each n-contact interconnect 32 is provided in a separate opening of the active LED structure 14. The reflective layer interconnects 82 are also arranged in an array where multiple reflective layer interconnects 82 are positioned between adjacent pairs of n-contact interconnects 32. In certain embodiments, the n-contact interconnects 32 and the reflective layer interconnects 82 collectively form a symmetric pattern across the active LED structure 14. In certain embodiments, diameters of reflective layer interconnects 82 may vary according to respective distances from an n-contact interconnect 32. For example, largest diameter reflective layer interconnects 82 may be positioned closest to n-contact interconnects 32 to promote increased current injection along mesa edges adjacent to the n-contact interconnects 32. In this regard, the layout 90 provides increased current spreading and/or injection for large area LED chip structures with bonding structures and carrier substrates as described above.

In certain embodiments, the principles of the present disclosure are advantageous for embodiments that include additional light extraction structures incorporated at various internal interfaces of LED chips. For example, light extraction features may be incorporated between carrier substrates and bonding structures that include random or ordered features the further reduce internal reflections.

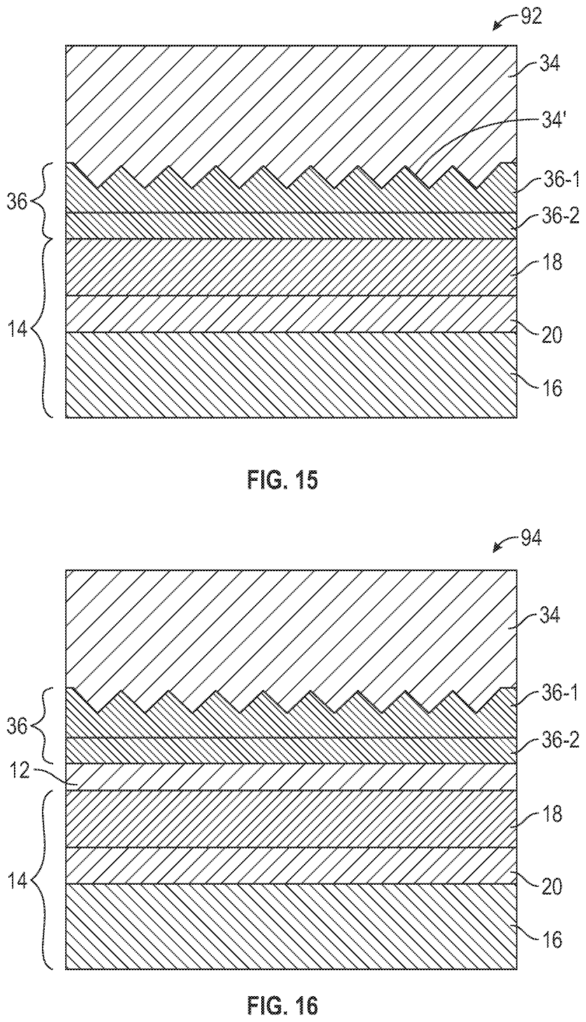

FIG. 15 is a general cross-section of an LED chip 92 that is similar to the LED chip 74 of FIG. 12 and further includes light extraction features on a surface 34′ of the substrate 34 that forms an interface with the bonding layer 36. As illustrated, the surface 34′ includes multiple recessed and/or raised light extraction features that provide a nonplanar interface with the bonding layer 36, thereby reducing internal reflections therebetween. The light extraction features may include random texturing or a patterned structure of features that repeat. In either case, the bonding sublayer 36-1 may be formed to cover the surface 34′ and corresponding light extraction features such that a generally planar surface is formed at an interface with the bonding sublayer 36-2. Accordingly, the oxide-to-oxide bonding may occur at the generally planar surface for increased mechanical strength.

FIG. 16 is a general cross-section of an LED chip 94 that is similar to the LED chip 92 of FIG. 15 and further includes the antireflective structure 12. In this manner, the LED chip 94 is similar to the LED chip 88 of FIG. 13 and further includes the surface 34′ of the substrate 34 described above for FIG. 15. The antireflective structure 12 may be positioned between the active LED structure 14 and the bonding layer 36 as previously described. In this manner, the antireflective structure 12 increases amounts of light passing into the bonding layer 36 and in turn, the surface 34′ of the substrate 34 increases amounts of the light that may pass into the substrate 34 and ultimately escape the LED chip 94 in a desired emission direction. The antireflective structure 12 of FIG. 16 may be implemented according to any of the previous embodiments, including FIGS. 1 to 14.

According to principles of the present disclosure, arrangements of bonding layers and/or antireflective structures are provided. As indicated above, in certain embodiments when bonding layers and antireflective structures are both present, the bonding layers and antireflective structures may be separate layers with separate functions. In other embodiments, bonding layers as described herein may be integrated as one or more sublayers of antireflective structures. Such integrated structures are applicable to any of the embodiments of the present disclosure, including FIGS. 1 to 16. In this manner, the bonding layers as drawn in any of FIGS. 1 to 16 may be separate layers or integrated sublayers of the antireflective structures, when present.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A light-emitting diode (LED) chip, comprising:
a substrate;
an active LED structure on the substrate, the active LED structure comprising an n-type layer, a p-type layer, and an active layer between the n-type layer and the p-type layer; and
an antireflective structure between the active LED structure and the substrate.

2. The LED chip of claim 1, further comprising a bonding layer between the active LED structure and the substrate.

3. The LED chip of claim 2, wherein the bonding layer is between the antireflective structure and the substrate.

4. The LED chip of claim 2, wherein the antireflective structure is between the bonding layer and the substrate.

5. The LED chip of claim 2, wherein the antireflective structure is a single antireflective layer between the bonding layer and the substrate.

6. The LED chip of claim 5, wherein a composition of the single antireflective layer is graded such that an index of refraction of the single antireflective layer is graded between the bonding layer and the substrate.

7. The LED chip of claim 2, wherein the antireflective structure comprises a plurality of antireflective layers with index of refraction values that progressively decrease in a direction from the substrate toward the bonding layer.

8. The LED chip of claim 2, wherein the antireflective structure is a first antireflective structure, and the LED chip further comprises a second antireflective structure, wherein the bonding is layer between the first and second antireflective structures.

9. The LED chip of claim 1, wherein the antireflective structure comprises a first antireflective layer, a second antireflective layer, and a third antireflective layer, wherein the first and third antireflective layers have a first index of refraction, and the second antireflective layer has a second index of refraction that is different than the first index of refraction.

10. The LED chip of claim 1, wherein the p-type layer is between the antireflective structure and the n-type layer.

11. The LED chip of claim 1, wherein the n-type layer is between the antireflective structure and the p-type layer.

12. The LED chip of claim 1, wherein the active LED structure comprises aluminum indium gallium phosphide (AlInGaP) and the substrate comprises sapphire.

13. The LED chip of claim 1, further comprising a p-contact and an n-contact that are both on a side of the active LED structure that is opposite the substrate.

14. The LED chip of claim 1, further comprising:
at least one n-contact interconnect that extends through the p-type layer and the active layer to contact a portion of the n-type layer;
a dielectric reflector layer on the p-type layer;
a metal reflector layer on the dielectric reflector layer; and
a plurality of reflective layer interconnects that extend from the metal reflector layer and through the dielectric reflector layer.

15. The LED chip of claim 1, wherein a layer of the antireflective structure forms a bonding layer between the active LED structure and the substrate.

16. A light-emitting diode (LED) chip, comprising:
a carrier substrate;
a bonding layer on the carrier substrate;
an active LED structure on the substrate such that the bonding layer is between the active LED structure and the carrier substrate, the active LED structure comprising an n-type layer, a p-type layer, and an active layer between the n-type layer and the p-type layer;
a plurality of n-contact interconnects arranged to extend through the p-type layer and the active layer to contact a portion of the n-type layer;
a dielectric reflector layer on the p-type layer;
a metal reflector layer on the dielectric reflector layer; and
a plurality of reflective layer interconnects that extend from the metal reflector layer and through the dielectric reflector layer to form an electrically conductive path to the p-type layer.

17. The LED chip of claim 16, wherein the dielectric reflector layer, the metal reflector layer, and the plurality of reflective layer interconnects are on an opposite side of the active LED structure from the bonding layer.

18. The LED chip of claim 16, wherein the active LED structure comprises aluminum indium gallium phosphide (AlInGaP) and the substrate comprises sapphire.

19. The LED chip of claim 16, further comprising a p-contact and an n-contact that are both on a side of the active LED structure that is opposite the carrier substrate.

20. The LED chip of claim 16, further comprising an antireflective structure between the active LED structure and the carrier substrate.

21. The LED chip of claim 20, wherein the antireflective structure comprises a first antireflective layer, a second antireflective layer, and a third antireflective layer, wherein the first and third antireflective layers have a first index of refraction, and the second antireflective layer has a second index of refraction that is different than the first index of refraction.

22. The LED chip of claim 20, wherein the bonding layer is part of the antireflective structure.

23-31. (canceled)
